(19) United States
(12) Patent Application Publication
(10) Pub. No.: US 2009/0152670 A1
(43) Pub. Date: Jun. 18, 2009

(54) SEMICONDUCTOR DEVICE AND METHOD OF FABRICATING THE SAME

(76) Inventor: Dae-Kyeun Kim, Yongin-si (KR)

Correspondence Address: SHERR & VAUGHN, PLLC, 620 HERNDON PARKWAY, SUITE 200, HERNDON, VA, 20170, US

(21) Appl. No.: 12/330,593

(22) Filed: Dec. 9, 2008

(30) Foreign Application Priority Data
Dec. 17, 2007 (KR) 10-2007-0131939

(51) Int. Cl. H01L 21/762; H01L 29/06

(52) U.S. Cl. 257/506; 438/435; 257/E29.02; 257/E21.546

(57) ABSTRACT

A semiconductor device and a method of fabricating the same includes a semiconductor substrate including a first trench; an epitaxial layer disposed on and/or over the semiconductor substrate and including a second trench connected to the first trench; a first insulator disposed in the first trench; and a second insulator disposed in the second trench.

The present application claims priority under 35 U.S.C. §119 to Korean Patent Application No. 10-2007-0131939 (filed on Dec. 17, 2007), which is hereby incorporated by reference in its entirety.

### BACKGROUND

As information processing technology has been developed, semiconductor chips of a high degree of integration and a high density are required. Especially, as semiconductor devices are highly integrated, their performance can be deteriorated due to electrical shorts.

### SUMMARY

Embodiments relate to a semiconductor device and a method of fabricating the same that can prevent electrical shorts between semiconductor devices.

In accordance with embodiments, a semiconductor device may include at least one of the following: a semiconductor substrate including a first trench; an epitaxial layer disposed on and/or over the semiconductor substrate and including a second trench connected to the first trench; a first insulator disposed in the first trench; and a second insulator disposed in the second trench.

In accordance with embodiments, a semiconductor device may include at least one of the following: a semiconductor substrate; an epitaxial layer disposed on and/or over the semiconductor substrate; and a device isolation layer penetrating the epitaxial layer, the device isolation layer including a first insulator disposed in a first trench in the semiconductor substrate, and a second insulator disposed in a second trench in the epitaxial layer.

In accordance with embodiments, a method of manufacturing a semiconductor device may include at least one of the following: forming a first trench on and/or over a semiconductor substrate; filling a first insulator in the first trench; forming an epitaxial layer on and/or over the semiconductor substrate; forming a second trench that corresponds to the first trench and penetrates the epitaxial layer; and filling a second insulator in the second trench.

In accordance with embodiments, a device may include at least one of the following: a semiconductor substrate including a first trench; an epitaxial layer formed over the semiconductor substrate, the epitaxial layer having a second trench connected to the first trench; a first insulator filling the first trench; and a second insulator filling the second trench.

In accordance with embodiments, a device may include at least one of the following: a semiconductor substrate having a first trench formed therein; an epitaxial layer formed over the semiconductor substrate, the epitaxial layer having a second trench formed therethrough; and a device isolation layer formed penetrating through the epitaxial layer and partially through the semiconductor substrate, the device isolation layer including a first device isolation layer portion formed in the first trench and a second device isolation layer portion formed in the second trench.

In accordance with embodiments, a method may include at least one of the following: forming a first trench in a semiconductor substrate; and then filling a first insulator in the first trench; and then forming an epitaxial layer over the semiconductor substrate including the first trench and the first insulator; and then forming a second trench penetrating through the epitaxial layer and spatially corresponding to the first trench; and then filling a second insulator in the second trench.

The semiconductor device in accordance with embodiments is insulated from adjacent semiconductor devices through first and second insulators disposed in first and second trenches, respectively. The semiconductor device is insulated by insulating materials disposed deeper because a second trench is formed on and corresponding to a first trench, and thus, prevents electrical shorts between it and adjacent semiconductor devices.

### DRAWINGS

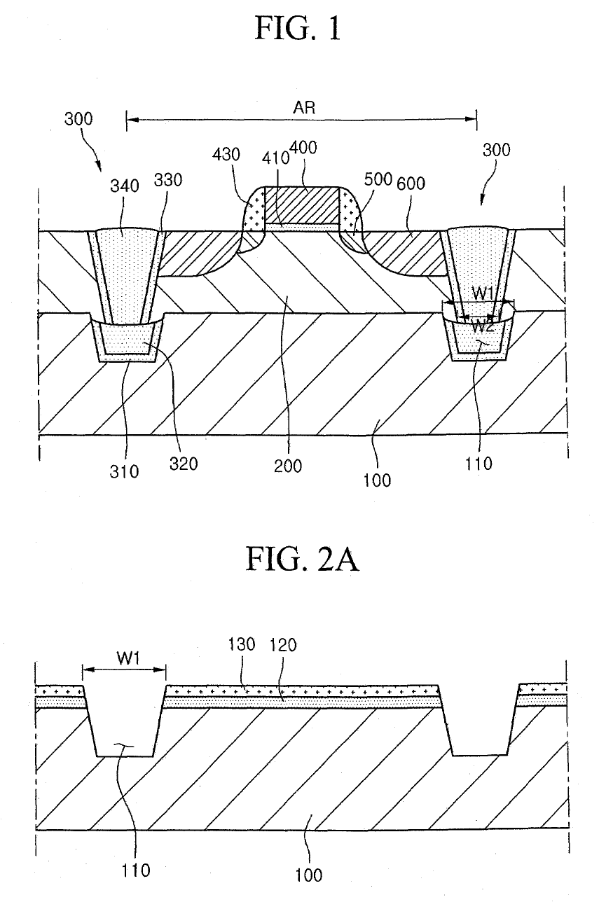

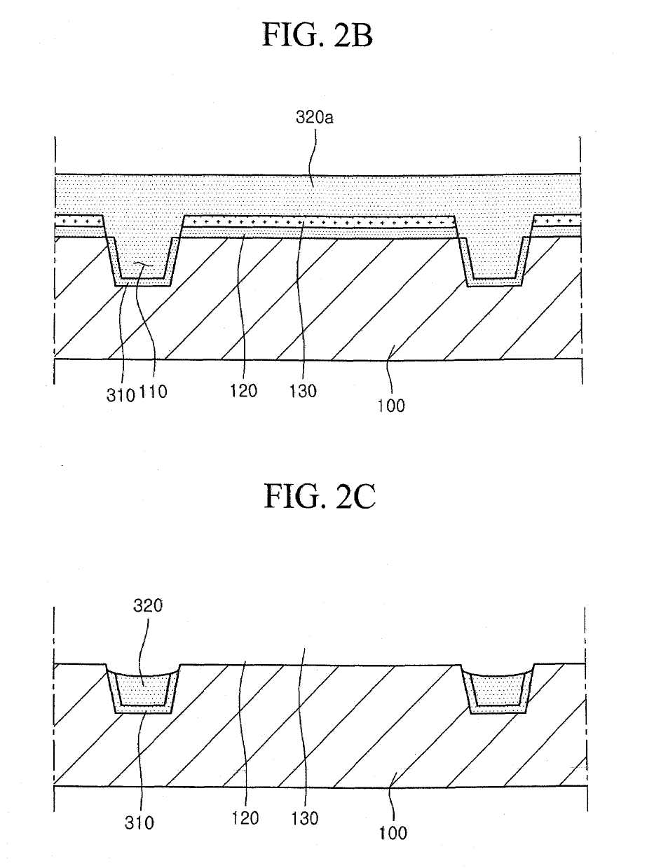

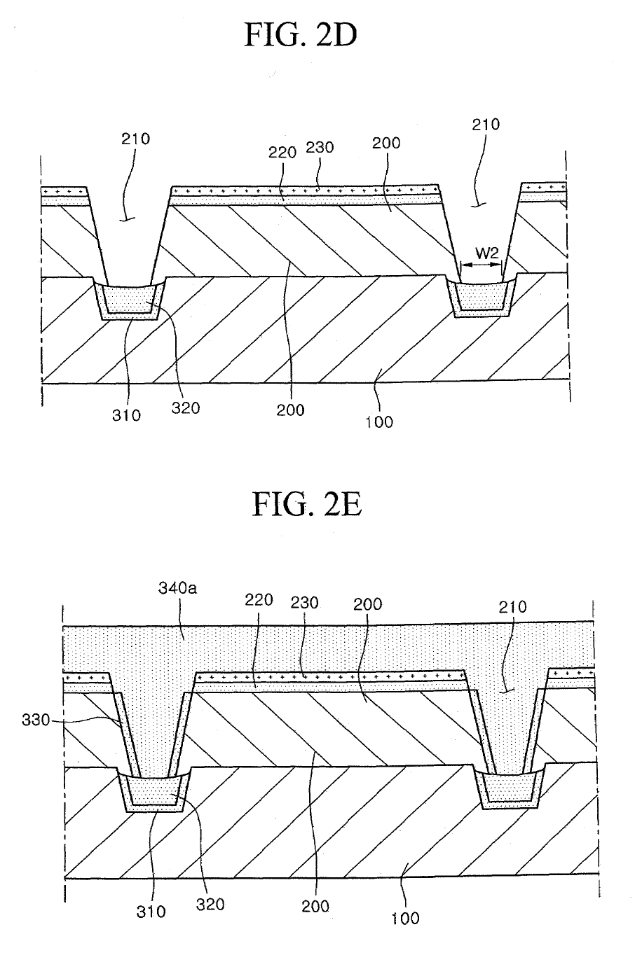

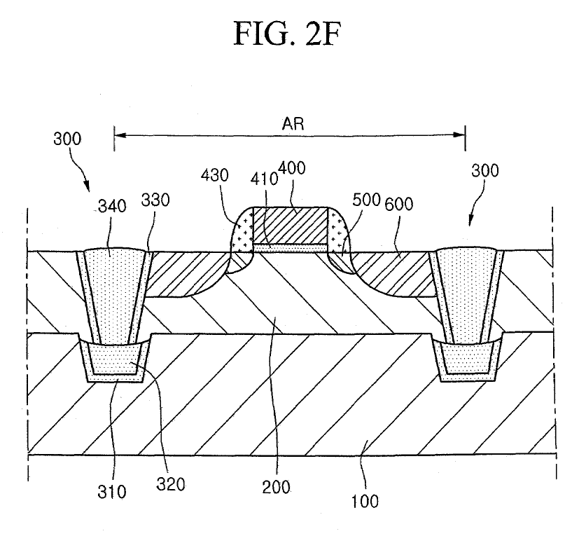

Example FIGS. 1 to 2 illustrate an NMOS transistor and a method of fabricating the same in accordance with embodiments.

### DESCRIPTION

Example FIG. 1 is a cross-sectional view of an NMOS transistor in accordance with embodiments. Referring to example FIG. 1, the NMOS transistor includes semiconductor substrate 100, epitaxial layer 200, device isolation layer 300, gate electrode 400 and source/drain region 600. Semiconductor substrate 100 has a rectangular cross-section. Single crystalline silicon may be used for semiconductor substrate 100. For example, an n-type impurity of a low concentration may be injected into semiconductor substrate 100.

First trench 110 is formed in semiconductor substrate 100. First trench 110 has an inlet having first width W1. Epitaxial layer 200 is formed on and/or over semiconductor substrate 100. For example, the epitaxial layer 200 may include a p-type impurity of a low concentration. Second trench 210 is formed in epitaxial layer 200 and penetrates epitaxial layer 200. Accordingly, second trench 210 has an upper inlet at an uppermost portion thereof and a lower inlet at a lowermost portion thereof. Second trench 210 is formed on and/or over first trench 110 and is connected to first trench 110. Particularly, the lower inlet of second trench 210 and the upper inlet of first trench 110 are connected to each other. The lower inlet of second trench 210 has second width W2. Second width W2 is less than first width W1. Accordingly, first trench 110 and second trench 210 have respectively different widths and are connected to each other. Moreover, first trench 110 is disposed at a depth in semiconductor substrate 100 lower than second trench 210.

Device isolation layer 300 is disposed in first trench 110 and second trench 210. Device isolation layer 300 is an insulator, and includes first oxide layer 310, first insulator 320, second oxide layer 330 and second insulator 340. First oxide layer 310 is formed in first trench 110. First insulator 320 is formed in first trench 110 and on and/or over first oxide layer 310. For example, first insulator 320 may include at least one of a silicon oxide (SiOₓ) and a silicon nitride (SiNₓ) material. Second oxide layer 330 is formed in second trench 210 and second insulator 340 is formed in second trench 210 and on and/or over second oxide layer 330. For example, second insulator 340 may include the same material as first insulator 320, particularly, at least one of a silicon oxide and a silicon nitride material. First oxide layer 310, first insulator 320, second oxide layer 330 and second insulator 340 may be formed of the same material. Meaning, first insulator 320 and second insulator 340 may be formed of an oxide used for first oxide layer 310 and second oxide layer 330.

Since first trench 110 and second trench 210 are connected to each other and have respectively different widths, first oxide layer 310 and first insulator 320 and also second oxide layer 330 and second insulator 340 have respectively different widths and are connected to each other. Meaning, device isolation layer 300 may be divided into an upper device isolation layer portion and a lower device isolation layer portion which are connected to each other and have respectively different widths. Each device isolation layer portion is tapered downwardly. Active region AR is defined in epitaxial layer 200 by device isolation layer 300.

Gate electrode 400 is formed on and/or over epitaxial layer 200 in active region AR. Gate electrode 400 may be formed of a material such as polycrystalline silicon or metal. Additionally, gate insulation layer 410 is formed interposed between gate electrode 400 and epitaxial layer 200 and serves to insulate gate electrode 400 from epitaxial layer 200. Source/drain region 600 is formed in epitaxial layer 200 at both sides of gate electrode 400. Source/drain region 600 includes an n-type impurity of a high concentration. Spacer 430 is formed at sidewalls of gate electrode 400 and gate insulating layer 410. Spacer 430 prevents electrical shorts between gate electrode 400 and source/drain region 600. Lightly doped drain (LDD) region 500 is formed in epitaxial layer 200 adjacent to source/drain region 600 and under and overlapping spacer 430. LDD region 500 includes an n-type impurity of a low concentration.

The semiconductor device in accordance with embodiments is insulated from other adjacent semiconductor devices through device isolation layer 300 disposed in first trench 110 and second trench 210. Since second trench 210 is formed on and/or over first trench 110, device isolation layer 300 may be formed deeper. Moreover, device isolation layer 300 has an upper portion and a lower portion connected to each other with respectively different widths. Since the width of the lower portion is broader than that of the upper portion, a path through which an electron circumvents device isolation layer 300 becomes lengthened. Therefore, the semiconductor device in accordance with embodiments has even greater insulation from other adjacent semiconductor devices.

Example FIG. 2A to 2F are cross-sectional views illustrating a method of fabricating a semiconductor device in accordance with embodiments. Referring to example FIG. 2A, first passivation layer 120 and first nitride layer 130 are formed on and/or over semiconductor substrate 100 where an n-type impurity of a low concentration is injected. An oxide may be used to from first passivation layer 120. First passivation layer 120, first nitride layer 130 and semiconductor substrate 100 are selectively partially etched to form first trench 110. First trench 110 has an inlet of first width W1.

Referring to example FIG. 2B, first oxide layer 310 is formed in first trench 110 through a thermal oxidation process and first insulator 320 is filled in first trench 110. First insulating material 320a is filled in first oxide layer 310 and stacked on and/or over first nitride layer 130.

Referring to example FIG. 2C, first insulating material 320a stacked on and/or over first nitride layer 130, first nitride layer 130 and first passivation layer 120 are removed from the uppermost surface of semiconductor substrate 100 through one of a chemical mechanical polishing (CMP) process and an etching process.

Referring to example FIG. 2D, after removing first insulating material 320a, first nitride layer 130, first nitride layer 130 and first passivation layer 120, silicon is deposited on and/or over semiconductor substrate 100 through a chemical vapor deposition process to grow epitaxial layer 200. Second passivation layer 220 and second nitride layer 230 are then deposited on and/or over epitaxial layer 200. Epitaxial layer 200, second passivation layer 220 and second nitride layer 230 are then etched to form second trench 210 penetrating through epitaxial layer 200 and exposing first insulator 320. Second trench 210 has an uppermost inlet and a lowermost inlet spatially corresponding to each other. Second width W2 of the lowermost inlet is less than the first width W1.

Referring to example FIG. 2E, second oxide layer 330 is formed on and/or over sidewalls of second trench 210 through a thermal oxidation process. Second insulating material 340a is filled in second trench 210 on sidewalls of second oxide layer 330 and stacked on and/or over second nitride layer 230.

Referring to example FIG. 2F, second insulating material 340a, second passivation layer 220 and second nitride layer 230 are removed from the uppermost surface of epitaxial layer 200 through one of a CMP process and an etching process. Device isolation layer 300 including first oxide layer 310, first insulator 320, second oxide layer 330 and second insulator 340 is thereby formed. Device isolation layer 300 is divided into a lower portion including first oxide layer 310 and first insulator 320 and an upper portion including second oxide layer 330 and second insulator 340. The upper portion and the lower portion have respectively different widths. First oxide layer 310, first insulator 320, second oxide layer 330 and second insulator 340 may be formed of the same material and may be integrated.

An insulation layer and a polysilicon layer are then formed on and/or over epitaxial layer 200 and then patterned to thereby form gate electrode 400 and gate insulation layer. Using gate electrode 400 as a mask, an n-type impurity is injected into active region AR to form LDD region 500. After forming a nitride layer on and/or over epitaxial layer 200, spacer 430 is formed through an anisotropic etching process. Then, using gate electrode 400 and spacer 430 as ion implantation masks, an n-type impurity of a high concentration is implanted in active region AR to form source/drain region 600.

The semiconductor device in accordance with embodiments is insulated from adjacent semiconductor devices through the use of first and second insulators disposed in first and second trenches, respectively. The semiconductor device is insulated by insulating materials disposed deeper because a second trench is formed on and/or over and corresponding to a first trench, and thus, prevents electrical shorts between it and adjacent semiconductor devices.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a semiconductor substrate including a first trench;
an epitaxial layer formed over the semiconductor substrate, the epitaxial layer having a second trench connected to the first trench;
a first insulator filling the first trench; and
a second insulator filling the second trench.

2. The device of claim 1, wherein the first insulator has a first width and the second insulator has a second width different than the first width.

3. The device of claim 2, wherein the first insulator and the second insulator are connected to each other.

4. The device of claim 1, further comprising an oxide layer formed at sidewalls of the first trench and the second trench.

5. The device of claim 1, wherein the semiconductor substrate comprises a first conductive type impurity.

6. The device of claim 5, wherein the epitaxial layer comprises a second conductive type impurity.

7. The device of claim 1, wherein the first insulator and the second insulator are formed of the same material.

8. The device of claim 1, wherein the first insulator and the second insulator include at least one of a silicon oxide (SiOₓ) and a silicon nitride (SiNₓ) material.

9. A device comprising:
a semiconductor substrate having a first trench formed therein;
an epitaxial layer formed over the semiconductor substrate, the epitaxial layer having a second trench formed therethrough; and
a device isolation layer formed penetrating through the epitaxial layer and partially through the semiconductor substrate, the device isolation layer including a first device isolation layer portion formed in the first trench and a second device isolation layer portion formed in the second trench.

10. The device of claim 9, wherein the first device isolation layer portion has a first width and the second device isolation layer portion has a second width less than the first width.

11. The device of claim 9, further comprising an oxide layer formed at sidewalls of the first trench and the second trench.

12. The device of claim 9, wherein the semiconductor substrate comprises a first conductive type impurity and the epitaxial layer comprises a second conductive type impurity.

13. The device of claim 10, wherein the first device isolation layer portion and the second device isolation layer portion are formed of the same material.

14. A method comprising:
forming a first trench in a semiconductor substrate; and then
filling a first insulator in the first trench; and then
forming an epitaxial layer over the semiconductor substrate including the first trench and the first insulator; and then
forming a second trench penetrating through the epitaxial layer and spatially corresponding to the first trench; and then
filling a second insulator in the second trench.

15. The method of claim 14, wherein the semiconductor substrate comprises a first conductive type impurity.

16. The method of claim 14, wherein forming of the epitaxial layer comprises:
forming the epitaxial layer over the semiconductor substrate; and then
injecting a second conductive type impurity into the epitaxial layer.

17. The method of claim 14, wherein forming the first trench comprises:
sequentially forming an oxide layer and a nitride layer over the semiconductor substrate; and then
etching the oxide layer, the nitride layer and the semiconductor substrate.

18. The method of claim 14, further comprising, after forming the first trench and before filling the first insulator:
forming a first oxide layer on sidewalls and a bottom surface of the first trench.

19. The method of claim 18, further comprising, after forming the second trench and before filling the second insulator:
forming a second oxide layer on sidewalls of the second trench.

20. The method of claim 14, wherein forming the second trench comprises exposing the uppermost surface of the first insulator.
